(19) United States
(12) Patent Application Publication
(10) Pub. No.: US 2007/0258278 A1
(43) Pub. Date: Nov. 8, 2007

(54) Memory module and methods for making and using the same

(76) Inventors: Abdallah Bacha, Muenchen (DE); Rainer Menes, Fuerstenfeldbruck (DE); Siva Raghuram, Germering (DE)

Correspondence Address: EDELL, SHAPIRO & FINNAN, LLC, 1901 RESEARCH BLVD., SUITE 400, ROCKVILLE, MD, 20850, US

(21) Appl. No.: 11/418,459

(22) Filed: May 5, 2006

(51) Int. Cl. G11C 5/02

(52) U.S. Cl. 365/51

(57) ABSTRACT

A memory module includes a first printed circuit board, wherein some of the memory chips in each of first and second ranks of memory chips are assembled on one side of the printed circuit board and others of the first and second ranks are assembled on the other side of the printed circuit board. First and second registers are respectively connected to the first and second address buses for respectively addressing the first and second ranks of memory chips. Since the addresses buses are separate for the two ranks, it is possible to activate only the address bus associated with the particular rank being addressed. In this manner, address activation power is saved by not activating the address bus of the other rank which is not addressed. Due to less power dissipation, it is possible to operate the memory module without a full DIMM heat spreader.

### BACKGROUND

In computer systems, random access memories (RAM) are often organized in memory ranks, a term that was created by JEDEC, the memory industries standards group. The concept of memory ranks applies to all memory module form factors, including desk top DIMMs (dual in-line memory modules), notebook SODIMM (small outline dual in-line memory module), and workstation and server registered DIMMs. A memory rank is a block or area of data that is created using some or all of the memory chips on a memory module.

A rank must be 64-bits of data wide. On memory modules which support error correction code (ECC), the 64-bit wide data area requires an 8-bit wide ECC area for a total width of 72-bits. Depending on how memory modules are engineered, they can contain one, two, or four areas/ranks of 64-bit wide data areas (or 72-bit wide areas/ranks, where 72 bits=64 data bits and 8 ECC bits).

Up to now, modules with memory chips on one side (single-sided modules) of printed circuit (PC) boards have always been single-rank. Double-sided unbuffered DIMMs and SODIMMs could be either single-rank or dual rank. Registered DIMMs, used for servers and workstations, vary from a single-rank to up to four ranks, whereby a double-sided registered DIMM can be:

single-rank, with all the memory chips on one/both sides representing a single 64-bit wide plus 8 bit ECC area;

dual-rank (with one rank per side), or if a stacked DRAM is used, the bottom and top die will be different ranks; or

quad-rank (with two ranks per side for a total of four ranks), or if a stacked DRAM is used, different dies in the stack will be different ranks.

In general, server memory modules are built using ×4 (“by four”) DRAM chips and are more expensive than rank memory modules (which are built using ×8 DRAM chips). Even if both module types have the same number of chips, the ×4 DIMMs (will be two ranks and with twice the memory size) are more expensive than ×8 DIMMs.

For such multiple rank modules, power consumption is very critical and the heat dissipated is very high.

### SUMMARY

According to an exemplary embodiment of the present invention, a memory module comprises: a PC board, a first rank of memory chips assembled on the PC board, and a second rank of memory chips assembled on the PC board, wherein a first part (some number) of the memory chips of the first rank is assembled on one side of the PC board and the other part of the memory chips of the first rank is assembled on the other side of the PC board, and a first part of the memory chips of the second rank is assembled on the one side of the PC board, and the other part of the memory chips of the second rank is assembled on the other side of the PC board.

The memory chips of first rank can be assembled on one half of the PC board (e.g., the lower half), while the memory chips of the second rank can be assembled on the other half of the PC board (e.g., the upper half). In this way, the Command Address bus to the ranks can be separated, and can be activated (addressed) only when that particular rank access is required. Due to this organization of memory chips, it is possible to reduce the switching power that is necessary for switching the Command Address bus.

In a further embodiment of the present invention, a memory module comprises: a PC board, a first rank of memory chips assembled on the PC board, a second rank of memory chips assembled on the PC board, a first address bus connected to the first rank of memory chips, and a second separate address bus connected to the second rank of memory chips. With this embodiment, the separated ranks can be driven by separate registers or separate command address bus copies within the same register, which can be turned on only when that particular rank is addressed by the memory controller. This reduces the power required for switching the command address (CA)-bus. This method may be used for modules with four ranks as well, where each DRAM is replaced by a stacked DRAM.

In a further embodiment, a method for using a memory module, which comprises a PC board, a first rank of memory chips assembled on the PC board, a second rank of memory chips assembled on the PC board, a first address bus connected to the first rank of memory chips, and a second address bus connected to the second rank of memory chips, is described, wherein only the address bus of the rank which is addressed is activated. In this manner, switching power is saved by not activating the address bus of the other rank, which is not addressed. Since the switching power is less, the module dissipates less power and can be operated without a full DIMM heat spreader.

In a further embodiment, a method for manufacturing a memory module is presented, involving: assembling a first part (some number) of a first rank of memory chips on one side of a PC board, assembling a second part of the first rank of memory chips on the other side of the PC board, assembling a first part of the second rank of memory chips on one side of the PC board, and assembling a second part of the second rank of memory chips on the other side of the PC board. An advantage of this embodiment is the possibility of reducing the power consumption and the heat dissipation due to the fact that switching load is reduced as both the ranks can be split and can be driven separately.

In a further embodiment, a method for manufacturing a memory module is presented, which comprises: assembling a first rank of memory chips on a PC board, assembling a second rank of memory chips on the PC board, and providing a first address bus, which is connected to the first rank of memory chips, and providing a second address bus, which is connected to the second rank of memory chips. An advantage of this separation is that the separated ranks can be driven by a separate register or separate command address bus copy within the same register which can be turned on only when that particular rank is addressed by the memory controller. This reduces the power required for switching CA bus.

A computer system with a memory module as described exhibits the same advantages as described above.

### BRIEF DESCRIPTION OF THE DRAWINGS

Detailed embodiments of the present invention are now described with reference to the views of the drawing.

FIG. 1A shows schematically a view from above on one of the sides of a PC board in accordance with an exemplary embodiment of the present invention.

FIG. 1B is showing schematically a side view of a memory module with memory chips of a first and a second rank divided on both sides of the PC board, in accordance with an exemplary embodiment of the present invention.

FIG. 2A shows schematically a top side of an assembled conventional PC board with memory chips, with memory chips of one rank being assembled on one side of the PC board.

FIG. 2B shows schematically a side view of a conventional memory module, wherein the memory chips of one rank are assembled on one side of the PC board.

FIG. 3 shows schematically a computer system with a memory module connected to a socket of a mother board.

### DETAILED DESCRIPTION

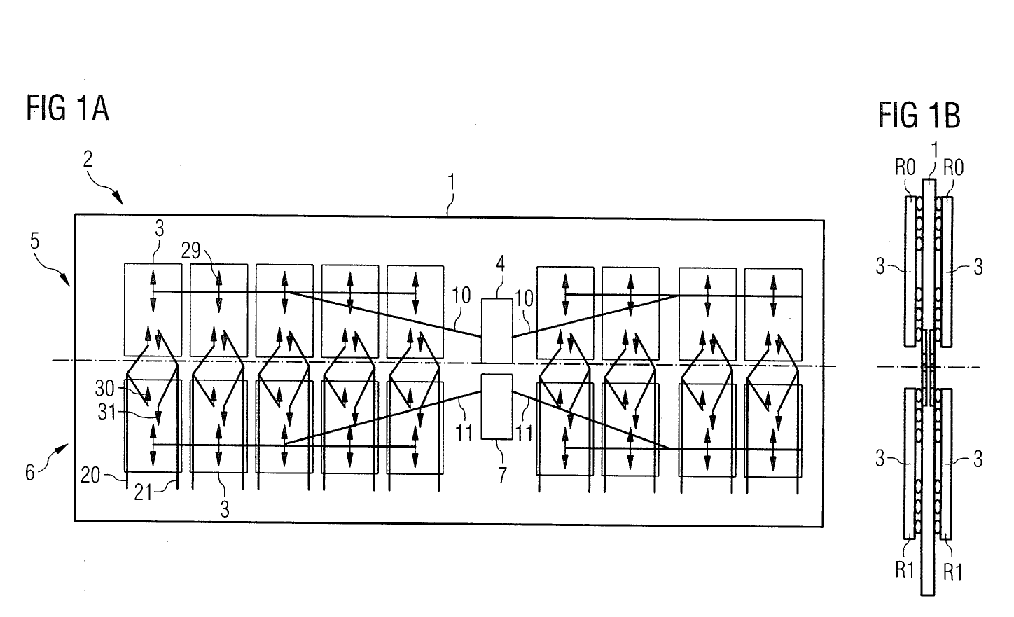

In FIG. 1A, a top plan view of a PC board 1 is depicted, on which a number of memory chips 3 are assembled. Together with a first register 4, a memory module 2 is built. The memory chips are assembled in two rows 5 and 6, wherein the memory chips 3 of the first row 5 belong to a first rank R0 and the memory chips 3 of the second row 6 belong to a second rank R1. In this embodiment, the memory chips 3 of the first rank R0 are addressed by a first register 4 via the first address bus 10, and the memory chips 3 of the second rank R1 are addressed via a second register 7 and the second address bus 11. The address bus is contacted to memory chips 3 on both sides of the PC board via contact holes in the PC board 1, as depicted schematically via an arrow 29. As more readily seen in FIG. 1B, on the other side of the PC board 1 there are assembled memory chips 3 of the same rank R0 or R1 so that it is easy to address the memory chips 3 on the other side of the PC board 1 with the help of via holes through the PC board 1. In order to read and write the data, each DRAM is connected to a data bus, whereas the data bus is split for contacting the memory chips 3 of both ranks on the PC board 1. Since the upper part of the PC board belongs to one rank and the lower part of the PC board belongs to the second rank, the data bus is split such that one branch of the data bus split is connected to DRAMs of rank one and the second branch of the data bus split is connected to DRAM chips of second rank. The data bus is used for both read and write to both the ranks of the memory module. With the help of the first and second registers 4,7, when the data bus is active, the rank to be actually addressed is chosen. To read/write from/to a particular rank, the address bus is switched on (i.e., enabled) only for that particular rank; the address bus of the other rank is not switched on (i.e., it is disabled).

With this method and memory module, the separated ranks R0 and R1 can be driven by separate registers 4, 7 which can be turned on only in response to the corresponding particular rank R0 or R1 being addressed by the memory controller.

The method may be used for modules with four ranks as well, where each memory chip 3 is replaced by a stacked DRAM.

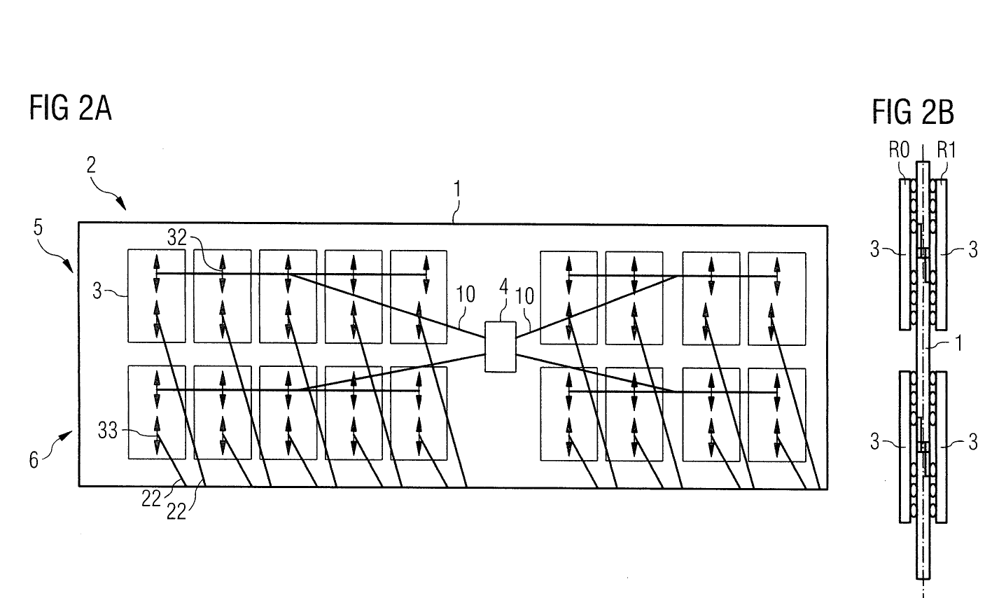

In FIG. 2A, the conventional arrangement of memory chips 3 on a PC board 1 is depicted. In this structure every memory chip 3 on one side of the PC board 1 belongs to one of the ranks R0, R1, and a first register 4 placed on the same surface side of the PC board 1 is used to address the memory chips 3 of this particular rank. A second register 7 (not depicted here) is assembled on the backside of the PC board in order to address the memory chips of the second rank R1. The first register 4 addresses the memory chips 3 of the first rank R0 via a first address bus 10. In an embodiment with only one register 4, but two separate command/address bus copies within the same register 4, the memory chips 3 of the second rank R1, which are assembled on the bottom side of the PC board 1 are addressed with the address bus 10 via contact holes in the PC board (which is depicted schematically with arrows 32). Consequently, the address buses for both the ranks R0, R1 are joined together, since this arrangement makes the connection simple using a via to go on the top and the bottom side of the PC board 1.

The data is provided via a data bus 22, which in the conventional arrangement has a wiring on one side of the PC board 1 and is contacting a memory chips 3 on the other side of the PC board 1 with the help of via hole (depicted schematically with arrows 33). Accordingly, the data bus of both of the ranks R0, R1 are connected together, which is desired in this connection.

The address bus (CA-bus) normally is 26-28 bits wide. In this conventional scheme, if either of the ranks R0, R1 has to be addressed, then the command address of both the ranks R0, R1 should be addressed/switched, which will result in higher power consumption/heat dissipation.

For example, a conventional memory module 2 with 36 DRAMS (18 DRAMs on each side of the PC board 1) for a 2R×4 (two ranks in a “×4” configuration) and therefore 36 DRAMs to be switched by two or four (two pairs) registers, each DRAM having a capacitance of about 1.5 pF, with 28 CA-BUS lines (command & address bus lines) would result in a DRAM load of 1.5 pF*28*36=1512 pF. With a PC board trace capacitance of about 10 pF and 4 address bus copies (in FIG. 2A the four address buses 10), a total net capacitance of 28*10 pF*4=1120 pF will result, thereby giving a total capacitance of 2632 pF. With a switching frequency of 100 Mhz (200 Mbit) for DDR2-400 (double data rate) specification (according to JEDEC) and a supply voltage of 1.8V, a total switching power (1.8V*1.8V*100 MHz*2632F=0.8 W) of 0.8 W results.

A memory module 2 according to an exemplary embodiment of the present invention (FIG. 1A) with 36 DRAMS (18 DRAMs on each side of the PC board 1) for a 2R×4 (two ranks in a “×4” configuration) and therefore only 18 DRAMs to be switched by one register, each DRAM having a capacitance of about 1.5 pF, with 28 CA-BUS lines (command & address bus lines) results in a DRAM load of 1.5 pF*28*18=756 pF. With a PC board trace capacitance of about 10 pF and 2 address bus copies (in FIG. 1A the left and right bus with respect to the register 4), each address bus a total net capacitance of 28*10 pF*2=660 pF will result, thereby giving a total capacitance of 1416 pF. With a switching frequency of 100 Mhz (200 Mbit) for DDR2-400 (double data rate) specification (according to JEDEC) and a supply voltage of 1.8V a total switching power (1.8V*1.8V*100 MHz*1416 pF=0.4 W) of 0.4 W results, which is only half of the switching power of the conventional memory module.

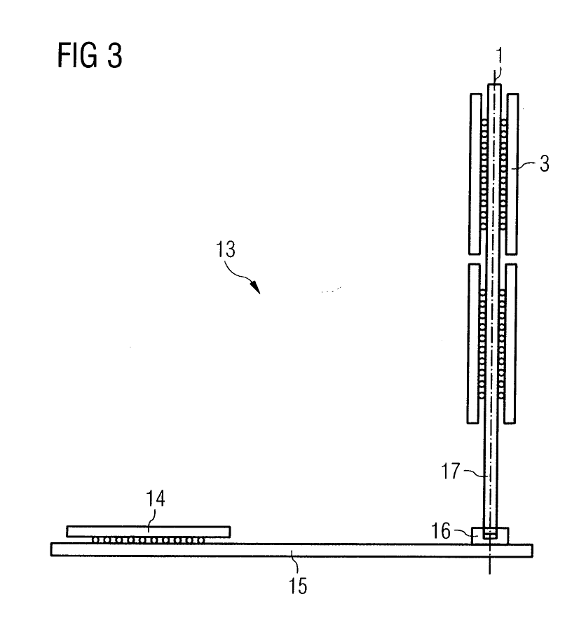

FIG. 3 shows schematically a computer system 13, which comprises a central processing unit 14 (CPU), which is assembled on a surface of a motherboard 15. The motherboard comprises a socket 16, in which additional memory modules, as described in this application, may be inserted using an edge connector 17.

This method can also be implemented in DDR3, where the address bus is “fly by bus” with end termination.

The invention may be embodied in other specific forms without departing from the spirit or essential characteristics thereof. The present embodiments are therefore to be considered in all respects as illustrative and not restrictive, the scope of the invention being indicated by the appending claims rather than by the foregoing description and all changes which come within the meaning and the range of equivalency of the claims are therefore intended to be embraced therein.

What is claimed is:

1. A memory module, comprising:
a printed circuit board; and
first and second ranks of memory chips assembled on the printed circuit board, wherein:
some of the memory chips of the first rank are assembled on one side of the printed circuit board and others of the memory chips of the first rank are assembled on the other side of the printed circuit board; and
some of the memory chips of the second rank are assembled on the one side of the printed circuit board and others of the memory chips of the second rank are assembled on the other side of the printed circuit board.

2. The memory module according to claim 1, further comprising:
a first address bus connected to the first rank of memory chips; and
a second address bus connected to the second rank of memory chips.

3. The memory module according to claim 2, further comprising:
a first register or a first pair of registers connected to the first address bus, and a second register or a second pair of registers connected to the second address bus.

4. The memory module according to claim 2, further comprising:
a first register or a first pair of registers connected to the first and the second address buses.

5. The memory module according to claim 1, further comprising:
a data bus connected to the first and second ranks of memory chips.

6. The memory module according to claim 1, further comprising:
a third rank of memory chips assembled on the printed circuit board, wherein some of the memory chips of the third rank are assembled on the one side of the printed circuit board and others of the memory chips of the third rank are assembled on the other side of the printed circuit board.

7. The memory module according to claim 6, further comprising:
a fourth rank of memory chips assembled on the printed circuit board, wherein some of the memory chips of the fourth rank are assembled on the one side of the printed circuit board and others of the memory chips of the fourth rank are assembled on the other side of the printed circuit board.

8. The memory module according to claim 7, wherein the third rank of memory chips is stacked with the first rank of memory chips, and the fourth rank of memory chips is stacked with the second rank of memory chips.

9. The memory module according to claim 1, further comprising:
a plurality of further ranks of memory chips assembled on the printed circuit board, wherein some of the memory chips of each rank are assembled on the one side of the printed circuit board and others of the memory chips of each rank are assembled on the other side of the printed circuit board.

10. The memory module according to claim 1, wherein said some and said others of the first rank of memory chips are situated directly opposed to one another on the two sides of the printed circuit board.

11. The memory module according to claim 1, wherein one half of a total number of memory chips of the first rank comprises said some of the memory chips of the first rank, and the other half of the total number of memory chips of the first rank comprises said others of the memory chips of the first rank.

12. A memory module, comprising:
a printed circuit board;
first and second ranks of memory chips assembled on the printed circuit board;
a first address bus connected to the first rank of memory chips; and
a second address bus connected to the second rank of memory chips.

13. The memory module according to claim 12, further comprising a first register or a first pair of registers connected to the first address bus, and a second register or a second pair of registers connected to the second address bus.

14. The memory module according to claim 12, further comprising a data bus connected to the first and second ranks of memory chips.

15. A memory module, comprising:
a printed circuit board;
first and second ranks of memory chips assembled on the printed circuit board;
first means for addressing the first rank of memory chips; and
separate second means for addressing the second rank of memory chips.

16. A method for using a memory module comprising a printed circuit board, first and second ranks of memory chips assembled on the printed circuit board, first and second address buses respectively connected to the first and second ranks of memory chips, and at least one register for controlling the first and second address buses, the method comprising:
supplying to the at least one register an address signal addressed to one of the first and second ranks of memory chips; and
activating only the address bus of the rank that is addressed by the address signal.

17. A method for manufacturing a memory module, comprising:
assembling some of a first rank of memory chips on one side of a printed circuit board;
assembling others of the first rank of memory chips on the other side of the printed circuit board;
assembling some of a second rank of memory chips on the one side of the printed circuit board; and
assembling others of the second rank of memory chips on the other side of the printed circuit board.

18. The method for manufacturing a memory module according to claim 17, further comprising:
connecting a first address bus to the first rank of memory chips; and
connecting a second address bus to the second rank of memory chips.

19. The method for manufacturing a memory module according to claim 18, further comprising:
connecting a first register or a first pair of registers to the first address bus; and
connecting a second register or a second pair of registers to the second address bus.

20. The method for manufacturing a memory module according to claim 18, further comprising:
connecting a data bus to the first and second ranks of memory chips.

21. The method for manufacturing a memory module according to claim 17, further comprising:
assembling some of further ranks of memory chips on the one side of the printed circuit board; and
assembling others of the further ranks of memory chips on the other side of the printed circuit board.

22. The method for manufacturing a memory module according to claim 21, wherein said some of one of the further ranks of memory chips are stacked on the memory chips of said some of the first rank, and said others of the one of the further ranks of memory chips are stacked on the memory chips of said others of the first rank.

23. The method for manufacturing a memory module according to claim 17, wherein said some and said others of the first rank are situated directly opposed to each other on the two sides of the printed circuit board.

24. A method for manufacturing a memory module, comprising:
assembling a first rank of memory chips on a printed circuit board;
assembling a second rank of memory chips on the printed circuit board;
connecting a first address bus to the first rank of memory chips; and
connecting a second address bus to the second rank of memory chips.

25. The method for manufacturing a memory module according to claim 24, further comprising:
connecting a first register or a first pair of registers to the first address bus; and
connecting a second register or a second pair of registers to the second address bus.

26. The method for manufacturing a memory module according to claim 24, further comprising:
connecting a data bus to the first and second ranks of memory chips.

27. A computer system comprising a memory module according to claim 1.

28. A computer system comprising a memory module according to claim 12.

29. A computer system comprising a memory module according to claim 15.
